(19) United States
(12) Patent Application Publication
(10) Pub. No.: US 2024/0365653 A1
(43) Pub. Date: Oct. 31, 2024

(54) HYBRID MESH-BASED FOLDABLE DISPLAY BACKING

(71) Applicant: GOOGLE LLC, Mountain View, CA (US)

(72) Inventors: William Riis HAMBURGEN, Mountain View, CA (US); Kiarash VAKHSHOURI, Mountain View, CA (US); Ion BITA, Mountain View, CA (US)

(21) Appl. No.: 18/685,975

(22) PCT Filed: Aug. 24, 2022
(86) PCT No.: PCT/US22/75443

§ 371 Date: Feb. 23, 2024

Related U.S. Application Data
(60) Provisional application No. 63/260,605, filed on Aug. 26, 2021.

(51) Int. Cl. H10K 77/10; G06F 1/16; H10K 71/50; H10K 102/00

(52) U.S. Cl. CPC H10K 77/111; H10K 71/50; G06F 1/1652; G06F 1/1656; H10K 2102/311

(57) ABSTRACT

A foldable display device includes: a foldable display layer, and a backing film coupled to the display layer. The backing film has a stiffness in a first direction parallel to a bending axis of a plane of the display layer that is at least ten times higher than a stiffness of the backing film in a second direction perpendicular to the bending axis in the plane of the display layer. The backing film includes a plurality of metal fibers arranged parallel to each other in the first direction and a film that mechanically couples the plurality of metal fibers to each other and that mechanically couples the plurality of metal fibers to the display layer, where the film includes material that has a modulus of elasticity that is less than 3% of a modulus of elasticity of a material of the plurality of metal fibers.

### CROSS-REFERENCE TO RELATED APPLICATION

This application claims priority to U.S. Provisional Patent Application No. 63/260,605, filed on Aug. 26, 2021, entitled “HYBRID MESH-BASED FOLDABLE DISPLAY BACKING”, the disclosure of which is incorporated by reference herein in its entirety.

### BACKGROUND

This description relates to wire cloth, thin polymer and metal sheets, and thin film materials and, in particular, to hybrid mesh-based thin films for foldable display backings.

Modern computing devices often attempt to achieve a balance between portability and functionality. A tension can exist between having a display that provides for a rich display of information on a single surface, which suggests a relatively large form factor of the device to accommodate a relatively large display, and a device that is small enough to be easily carried and accessed by a user, which suggests a relatively small form factor of the device.

A potential solution to address this dilemma is to use a foldable flexible display in the computing device, so that in the display's folded configuration, the computing device has a relatively small form factor, and in the display's unfolded configuration, the computing device can have a relatively large display. To keep the form factor of the computing device small and slim, it is desirable to have relatively thin displays. However, folding a relatively thin display can result in small radius and poorly controlled bends at the fold in the display, which may be detrimental to sensitive components of the display, for example, thin film transistors (TFTs), organic light-emitting diodes (OLEDs), thin-film encapsulation (TFE) and the like. In addition, thin displays can be relatively fragile and in need of protection against breakage, for example, protection against breakage from impacts to the front surface of the device, such as, due to “pen drop” impacts that concentrate an impact force on a small area of the display.

Accordingly, relatively thin, foldable displays that nevertheless can be bent in a small radius, but not beyond a minimum radius, and that are relatively sturdy, are desirable for use in computing devices.

However, it can be difficult to create a foldable top-emitting OLED display that has a small folding radius, that does not impart damaging stresses to the components of the display during folding and unfolding, and that can survive many fold-unfold cycles. Furthermore, flexible displays can be susceptible to warpage at locations where they are repeatedly bent, which also degrades the appearance of the display for a user.

### SUMMARY

As described herein, backing film having, or being fabricated from, a mesh material can be used to provide support and strength to a foldable display. The backing films can be created such that they resist bending in a first direction and that are easily bent in a second direction that is perpendicular to the first direction.

In some aspects, the techniques described herein relate to a foldable electronic display device including: a foldable display layer configured for displaying information to a user; and a backing film coupled to the foldable display layer and arranged substantially parallel to a display surface of the foldable display layer. The backing film is configured to have a stiffness in a first direction parallel to a bending axis of a plane of the foldable display layer that is at least ten times higher than a stiffness of the backing film in a second direction perpendicular to the bending axis in the plane of the foldable display layer. The backing film includes a plurality of metal fibers arranged parallel to each other in the first direction and a film that mechanically couples the plurality of metal fibers to each other and that mechanically couples the plurality of metal fibers to the foldable display layer, where the film includes material that has a modulus of elasticity that is less than 3% of a modulus of elasticity of a material of the plurality of metal fibers.

Example implementations can include one or more of the following features, alone, or in any combination with each other.

For example, the plurality of metal fibers can include a stainless steel material.

For example, the film can include a polyimide material.

For example, the foldable display layer can include an OLED layer.

For example, a neutral plane of the foldable electronic display device can coincide with a plane within the foldable display layer.

For example, the backing film can include a woven mesh material having warp fibers and shute fibers woven between the warp fibers, where the shute fibers have a modulus of elasticity that is less than 3% of a modulus of elasticity of the warp fibers, and where the plurality of metal fibers include the warp fibers of the woven mesh material.

For example, the shute fibers can include spandex or elastane.

For example, the backing film further can include a polymer material that encapsulates the plurality of metal fibers.

For example, the polymer material can be broken into a plurality of distinct sections, each section encapsulating a metal fiber of the plurality of metal fibers.

For example, the polymer material can include voids corresponding to locations of shute fibers of a woven mesh material, which have been removed from the mesh material, and where the plurality of metal fibers include warp fibers of the woven mesh material.

For example, the warp fibers can include stainless steel and the shute fibers can include aluminum.

For example, the plurality of metal fibers can have diameters that are less than 250 microns and that are spaced apart from each other by, on average, less than five times a diameter of individual fibers of the plurality of metal fibers.

In some aspects, the techniques described herein relate to a method of making a backing film for a foldable electronic display device having a foldable display layer configured for displaying information to a user, where the backing film has a stiffness in a first direction parallel to a bending axis of a plane of the foldable display layer that is at least ten times higher than a stiffness of the backing film in a second direction perpendicular to the bending axis in the plane of the foldable display layer. The method includes encapsulating a sheet of a woven mesh material having a plurality of warp fibers and a plurality of shute fibers, each shute fiber being woven between the warp fibers, in a polymer material, the warp fibers including a first material and the shute fibers including a second material that is different from the first material. The method includes selectively removing layers of the polymer material to expose portions of the shute fibers to a surface of the polymer material, the layers being parallel to a plane of the sheet of the woven mesh material. The method includes etching the shute fibers in a caustic bath to remove the shute fibers from the encapsulated sheet of woven mesh material. The method includes applying a film to the polymer material that encapsulates the warp fibers after the shute fibers have been removed by etching in the caustic bath, wherein the film includes material that has a modulus of elasticity that is less than 3% of a modulus of elasticity of a material of the warp fibers. Example implementations can include one or more of the following features, alone, or in any combination with each other.

For example, the warp fibers can include stainless steel, and the shute fibers can include aluminum.

For example, the film can include a polyimide material.

For example, the foldable display layer can include an OLED layer.

For example, a neutral plane of the foldable electronic display device can coincide with a plane within the display layer.

For example, the polymer material can be broken into a plurality of distinct sections, each section encapsulating a warp fiber of the plurality of warp fibers.

In some aspects, the techniques described herein relate to a method of making a backing film for a foldable display having a foldable display layer configured for displaying information to a user. The backing film has a stiffness in a first direction parallel to a bending axis of a plane of the foldable display layer that is at least ten times higher than a stiffness of the backing film in a second direction perpendicular to the bending axis in the plane of the foldable display layer. The method includes weaving a sheet of mesh material having a plurality of warp fibers and a plurality of shute fibers, each shute fiber being woven between the warp fibers, the warp fibers and the shute fibers having diameters of less than 250 microns, the warp fibers including a first material and the shute fibers including a second material that is different from the first material, where: the plurality of warp fibers includes a plurality of sections, each section including closely-spaced warp fibers and the sections being separated from each other by gaps of at least 1 cm, where the gaps include substantially parallel shute fibers; or the plurality of shute fibers includes a plurality of sections, each section including closely-spaced shute fibers and the sections being separated from each other by gaps of at least 1 cm, wherein the gaps include substantially parallel warp fibers. The method includes temporarily stabilizing the fibers in the gaps. The method includes, after the fibers in the gaps are temporarily stabilized, selectively removing the first material if the gaps include substantially parallel shute fibers or selectively removing the second material if the gaps include substantially parallel warp fibers. The method includes applying a low-modulus film to the fibers that remain after the first material or second material is selectively removed, where the film includes material that has a modulus of elasticity that is less than 3% of a modulus of elasticity of a material of the fibers that remain after the first or second material is selectively removed.

In an example implementation selectively removing the first or second material can include etching the woven mesh in a caustic bath.

### BRIEF DESCRIPTION OF THE DRAWINGS

FIG. 1 is a perspective view of a computing device that includes a foldable display with the foldable display in a partially folded configuration.

FIG. 2 is a perspective view of the computing device, with the display in a folded configuration.

FIG. 3 is a schematic diagram of a flexible display device having a stack of a number of different layers.

FIG. 4 is a schematic diagram of a foldable display having a bendable section that is bent around a minimum radius, Rmin.

FIG. 5 is a graph showing an example stiffness curve for a foldable display in which the limit radius is reached when the foldable display is folded.

FIG. 6 is a schematic diagram of another foldable display having a bendable section that is bent around a minimum radius, Rmin.

FIG. 7 is a schematic diagram of a mesh material having warp fibers and shute fibers.

FIG. 8 is a schematic diagram of a cross-section of a portion of the mesh material taken through line A-A′ of FIG. 7.

FIG. 9 is a schematic cross-sectional view taken through line A-A′ of FIG. 7 of a woven mesh material having stainless steel warp wires and aluminum shute wires that is encapsulated in a polymer material.

FIG. 10 is a schematic cross-sectional view taken through line A-A′ of FIG. 7 of the woven mesh material with stainless steel warp wires and aluminum shute wires that is encapsulated in the polymer material after portions of the polymer material have been removed to expose the aluminum shute wires to planar surfaces above and below the stainless steel warp wires.

FIG. 11 is a schematic cross-sectional view taken through line B-B′ of FIG. 7 of the woven mesh material with stainless steel warp wires after the aluminum shute wires have been removed.

FIG. 12 is a schematic cross-sectional view taken through line B-B′ of FIG. 7 of the woven mesh material with stainless steel warp wires after the aluminum shute wires have been removed and after the polymer material between the warp wires has been broken along break lines into separate sections.

FIG. 13 is a schematic cross-sectional view of a structure that includes a woven mesh material having stainless steel warp wires and aluminum shute wires that is encapsulated in a polymer material (e.g., epoxy, polyimide, a rubber-like material, such as polyethylene or polyurethane).

FIG. 14 is a schematic side view of a display device having a foldable OLED display layer that is supported by a mesh-based backing film, when the display device is configured in a flat orientation.

FIG. 15 is a schematic top view of a low modulus layer of the display device of FIG. 14 when the display device is configured in the flat orientation.

FIG. 16 is a schematic side view of the display device of FIG. 14 when a portion of the display device is folded and another portion of the display device is flat.

FIG. 17 is a schematic diagram of a mesh material having warp fibers and sections of shute fibers, where the sections of shute fibers are displaced from each other, leaving gaps without shute fibers between the sections.

FIG. 18 is a schematic diagram of a mesh material having warp fibers and sections of shute fibers, where the warp fibers in the gaps of FIG. 17 are temporarily stabilized.

FIG. 19 is a flowchart of a process of making a backing film.

FIG. 20 is another flowchart of a process of making a backing film.

### DETAILED DESCRIPTION

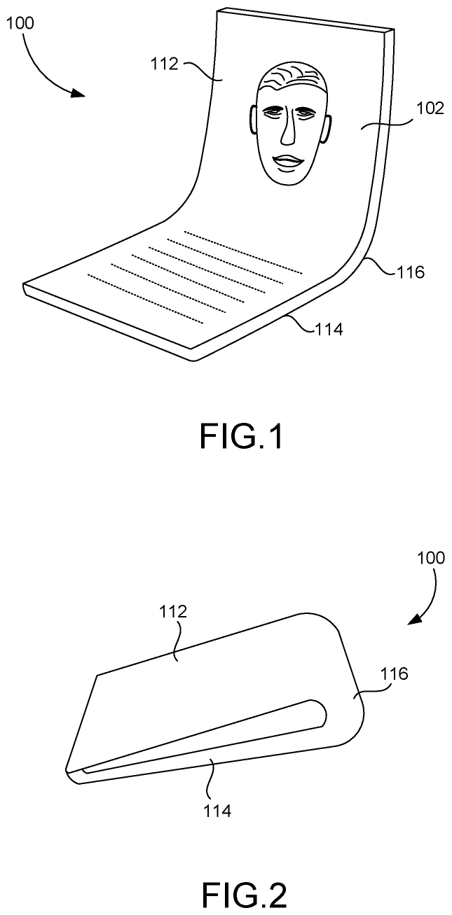

FIG. 1 is a perspective view of a computing device 100 that includes a foldable emissive (e.g., OLED, LED, LCD) or reflective (e.g., e-paper, e-ink) display 102, with the foldable display in a partially folded configuration. The computing device 100 has the foldable display 102 mounted so that it folds with the viewable face inward. It is also possible to mount the foldable display 102 on the opposite side of computing device 100 so that the display folds with its viewable face outward (not shown).

FIG. 2 is a perspective view of the computing device 100, with the foldable display 102 (shown in FIG. 1 but not in FIG. 2) in a folded configuration. The foldable display 102 may be, for example, a TFT (Thin-Film-Transistor) OLED (Organic Light Emitting Diode) display, or other appropriate display technology. The foldable display 102 may include appropriate circuitry for driving the display to present graphical and other information to a user.

As shown in FIG. 1 and in FIG. 2, the foldable display 102 can include a first relatively flat rigid, or-semi-rigid, section 112, a second flat rigid section 114, and a third bendable section 116. In some implementations, the foldable display 102 can include more than two flat rigid sections 112, 114 and more than one bendable section 116. In some implementations, the foldable display 102 can include zero, or only one, flat rigid section 112, 114. For example, when a foldable display 102 includes zero flat rigid sections, the foldable display 102 can be continuously bendable, and can be rolled up, as in a scroll. The foldable display 102 shown in FIG. 1 and FIG. 2 has a bendable section 116 that allows the foldable display to bend about a bend axis. In other implementations, the foldable display 102 can include bendable sections that allow the display to bend about more than one axis.

The bendable section 116 of the foldable display 102 allows the foldable display 102 to bend in an arc that has a radius, and the bendable section can be made to become rigid when the radius of the bendable section reaches a specified minimum radius. This minimum radius may be selected to prevent the display from bending in a radius so small that fragile components of the display would be broken. In some implementations, the minimum radius is greater than or equal to 0.5 millimeters, or greater than or equal to 1.0 millimeters, or greater than or equal to 2.0 millimeters, or greater than or equal to 3 millimeters. Thus, the bendable section can be flexible when bent in a radius greater than the minimum radius and then become rigid when the bend radius is equal to or smaller than the minimum radius.

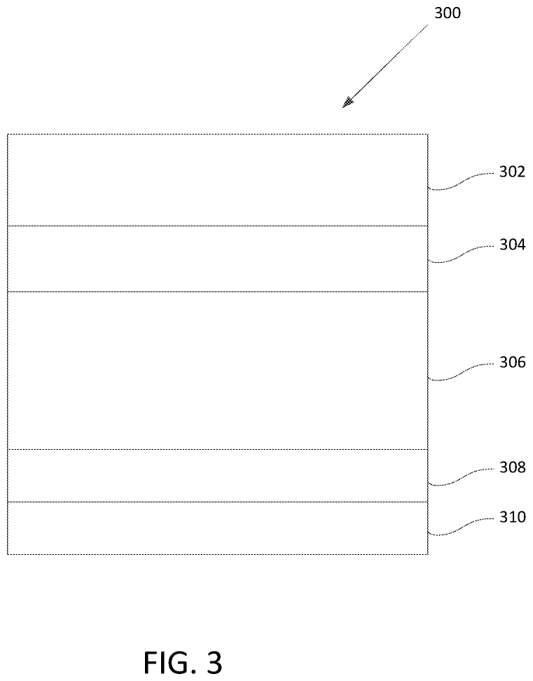

FIG. 3 is a schematic diagram of a flexible display device 300 having a stack of a number of different layers. For example, in some implementations, a flexible organic light-emitting diode (OLED) layer 306 can be supported by a backing film 308 and a bend limit layer 310. In some implementations, the backing film 308 can be between the OLED layer 306 and the bend limit layer 310. The OLED layer 306 of the schematic diagram of FIG. 3 includes an organic light emitting layer and also can include one or more of a thin-film transistor (TFT) layer, a touch layer having a pattern of electrodes for detecting a user's touch on the display, a color filter layer, a polarizer layer, and an encapsulation layer. In some implementations, the OLED layer 306 can be between the backing film 308 and the bend limit layer 310. An optically clear adhesive layer 304 can be applied to a front surface of the flexible OLED layer 306. A cover window film 302 can be applied to the optically clear adhesive layer 304 to protect the device on the front side. As the thickness of each layer of the stack is important to the overall thickness of the flexible display device 300, it is desirable to have a relatively thin thickness for the layers. For example, in some non-limiting examples, the thickness of the flexible OLED layer 306 can be on the order of approximately 150 μm; the thickness of the optically clear adhesive layer 304 can be on the order of approximately 50 μm; and the thickness of the cover window film can be on the order of approximately 30 μm. Thus, the thicknesses of the backing film 308 and the bend limit layer 310 each are fractions of a millimeter. In some implementations, the combined thickness of the bend limit layer 310, the OLED layer 306, and the backing film 308 can be less than two millimeters, or less than one millimeter. or less than 0.5 millimeters.

The components of the stack of the flexible display device 300 have different as-fabricated properties, including stresses and strains that exist in the component when the layer is fabricated. Additional stresses and strains can be induced in the layers of the stack when the display is bent into a configuration that is different from the configuration in which the layer was fabricated. For example, if the layer was flat when it was fabricated, then additional strain can be induced by stretching or bending the layer, and if the layer was fabricated in a curved configuration, then additional strain can be induced by flattening the layer. If the cyclic bend-induced strain exceeds a threshold value characteristic of a component of the stack, the component can be damaged by the strain due to cracking, buckling, delamination, etc. This characteristic damage threshold strain may be different depending on temperature, humidity, required cycle life, and other use and environmental factors. Brittle inorganic layers of the stack can typically withstand less strain than organic layers before they are damaged by the strain. Nevertheless, organic materials in the stack also can be damaged by excessive strain that is induced by bending.

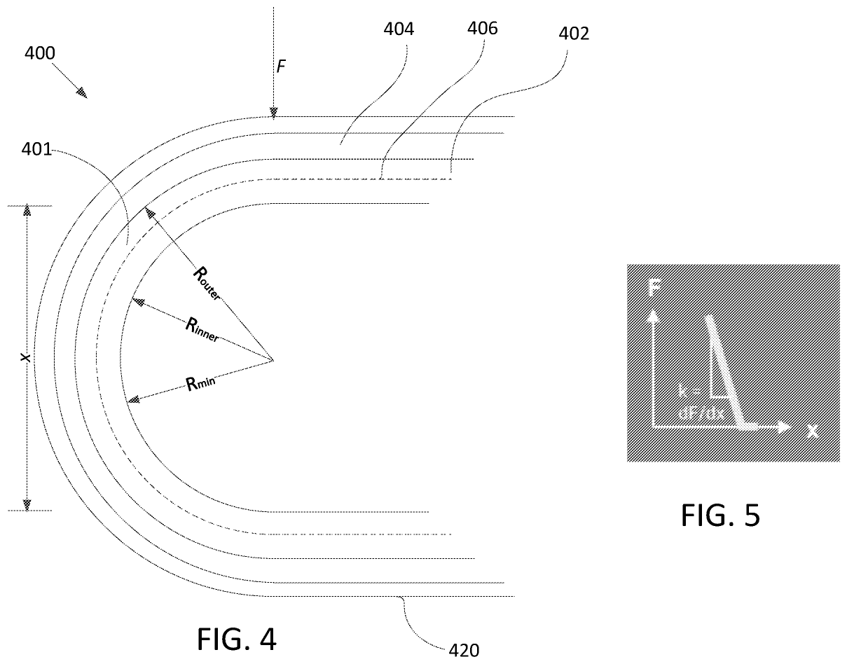

FIG. 4 is a schematic diagram of a foldable display 400 having a bendable section 401 (the curved portion shown in FIG. 4) that is bent around a minimum radius, Rmin and folds inward, toward the surface of the display. The foldable display 400 can include a display layer 402 that includes components (e.g., OLED layers, TFT layers, touch screen layers, polarizing layers, encapsulation layers, etc.) that generate images on the display (emitted from the side of the display that faces toward the inside of the bend) and that protect the image generating layers, and a bend limit layer 404 that limits the radius at which the foldable display 400 can bend to greater than or equal to some minimum radius, Rmin.

When the display layer 402 is fabricated in a flat configuration, then bending the display layer 402 in the absence of the bend limit layer 404 may cause the bendable section to assume a radius less than the minimum radius, Rmin and induce excessive strain within the display layer 402. For example, compressive strain will be induced along the inner radius of the bend, Rᵢₙₙₑᵣ, and tensile strain will be induced along the outer radius of the bend, Rₒᵤₜₑᵣ. An interior portion of the display layer 402 can be characterized by a plane at which no strain is induced when the display layer 402 is bent. This plane is referred to herein as the “neutral plane” 406. If the stack of materials within the display layer 402 is symmetrical about a midplane of the layer, then the neutral plane can correspond to the midplane of the layer. However, different material properties (e.g., thickness, Young's modulus, etc.) of different layers within the display layer 402 can cause the neutral plane to be displaced above or below the midplane of the layer 402. The location of the neutral plane within the display layer 402, along with the maximum tolerable strain values of the materials within the display layer 402, determines the minimum bend radius that can be tolerated without causing damage to components within the display layer 402.

The bend limit layer 404 can be coupled to the display layer 402 to provide support for the display layer 402 and can prevent the display layer from being bent around a radius that is smaller than its minimum tolerable bend radius. The bend limit layer 404 can be relatively flexible when it is bent in radii greater than Rₘᵢₙ and then can become stiff and inflexible when the radius of the bend approaches, or matches, Rₘᵢₙ. Stiffness can be parameterized by the change in bend radius per unit of applied force or moment that causes the foldable display 400 to bend. For example, in FIG. 4, when the display is folded in half around a 180 degree bend, twice the radius of the bend is shown by the parameter, x, when a force, F, is applied to bend the foldable display. The stiffness of the foldable display 400 then can be parameterized by the derivative, k=dF/dx. The strength of the foldable display can be characterized as the maximum force, F, that the foldable display 400 can withstand before failure of the display occurs.

When the foldable display 400 is laid flat in its folded configuration it can be maintained in its folded configuration by the force of gravity on the upper folded portion of the display, such that zero additional force is needed to be applied to the upper folded portion to maintain the foldable display in its flat folded configuration, or in other implementations, additional force can be applied by external means such as detents latches, magnets, etc. to maintain the display in its folded configuration. In this configuration the radius of the bend can be defined as the limit radius, Rₗᵢₘᵢₜ, i.e., the radius at which the bend limit layer 404 limits the further bending of the foldable display unless additional external force is applied. To bend the foldable display further from this configuration requires additional external force to overcome the stiffness of the bend limit layer. Thus, an example stiffness curve for a foldable display in which the limit radius is reached with the foldable display is folded 180 degrees, showing stiffness as a function of x is shown in FIG. 5.

It can be advantageous to have a foldable display with a stiffness curve that exhibits a relatively sharp increase in stiffness once the limit radius is reached, such that the foldable display can be easily folded into its folded configuration in which Rₗᵢₘᵢₜ is close to Rₘᵢₙ, and then the foldable display will become quite stiff, such that it remains in this configuration despite forces pressing it toward a radius smaller than Rₗᵢₘᵢₜ.

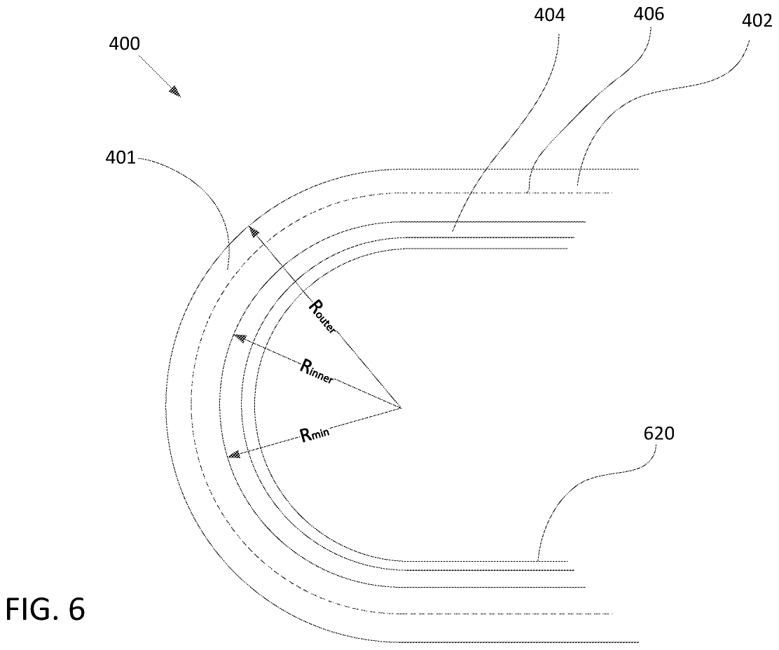

FIG. 6 is a schematic diagram of a foldable display having a bendable section that is bent around a minimum radius, Rₘᵢₙ. The bend limit layer 404 is shown on the outside of the bend in FIG. 4, but also can be on the inside of the bend, for example, as shown in FIG. 6, in which case the content displayed by the display is on the outside of the bend and the backing film 620 is on the inside of the bend.

A backing film 420, 620 of the device can provide strength and support for the device. Because thin OLED displays can be relatively fragile and are susceptible to breakage, the backing film 420 can provide protection against breakage from impacts to the front surface of the device, such as, due to “pen drop” impacts that concentrate an impact force on a small area of the display. However, with the backing film 420, 620 mechanically coupled to the display layer 402, the backing film 420, 620 can displace the neutral plane 406 toward the backing film, such that strain is introduced into the display layer 402 upon bending and/or unbending of the device 400 because of the different radii of curvature of the backing film 420, 620 and the display layer 402. To mitigate the introduction of strain to the display layer 402 by the backing film 420, 620, the backing film 420, 620 can be structured such that its stiffness is high in a first direction parallel to a bending axis of a plane of the display layer 402 (e.g., in a direction into the page in FIGS. 4 and 6) but is much lower in a second direction perpendicular to the bending axis in the plane of the display layer 402 (e.g., in a direction along the folded cross section of the display layer shown in FIGS. 4 and 6). In an implementation, the stiffness in the first direction can be at least ten times higher than the stiffness in the second direction. In an implementation, the stiffness in the first direction can be at least thirty times higher than the stiffness in the second direction. In an implementation, the stiffness in the first direction can be at least one hundred times higher than the stiffness in the second direction. In an implementation, the stiffness in the first direction can be at least one thousand times higher than the stiffness in the second direction. Such an anisotropic stiffness profile of the backing film 420, 620 can allow backing film to stretch easily in a direction perpendicular to the bending axis and for the film 420 to bend easily, without much resistance and without imparting much strain to the display layer 402 about the bending axis but to provide a high-strength support for the device that is relatively stiff in a direction perpendicular to the bending direction of the device.

Different structures can achieve such anisotropic stiffness profiles in the backing film 420, 620. For example, the backing film 420, 620 can include, or be fabricated from, one or more sheets of woven materials having different warp and shute materials or warp and shute materials having different material properties or from a sheet having parallel fibers running in one direction only.

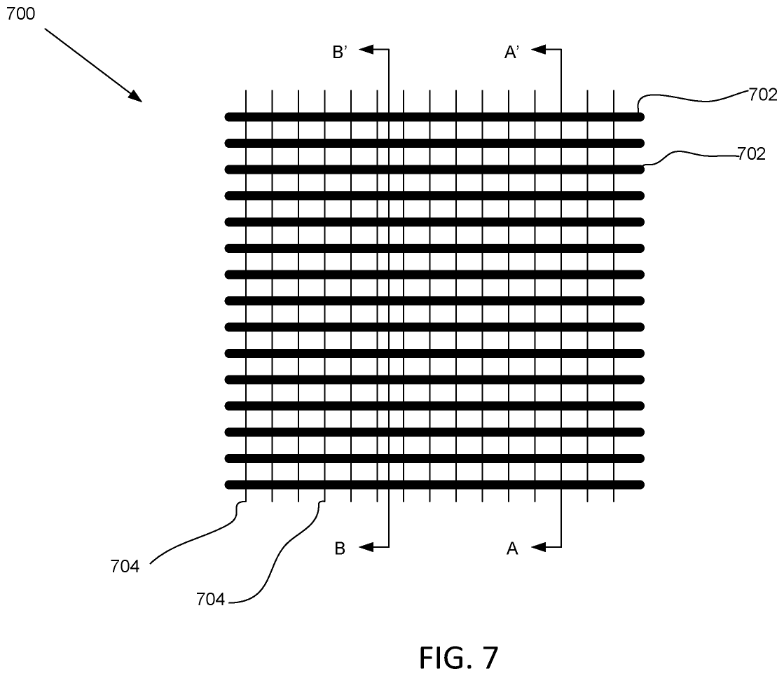

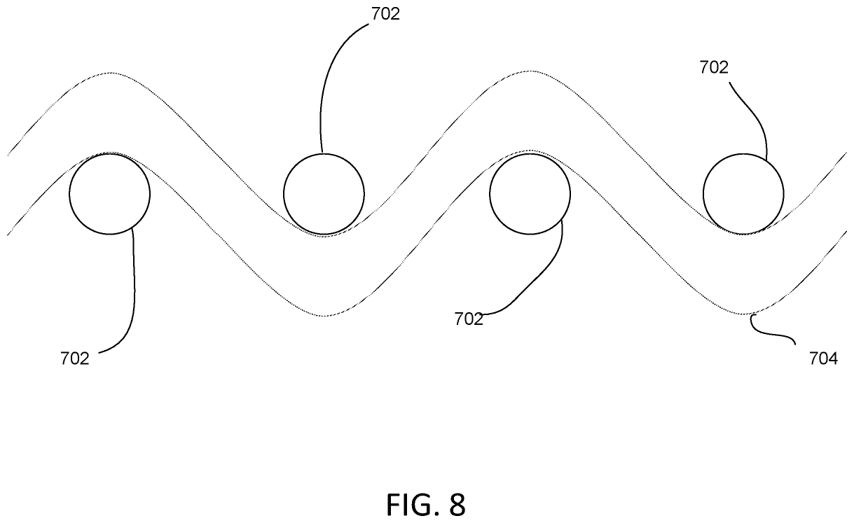

FIG. 7 is a schematic diagram of a mesh material 700 having warp fibers 702 and shute fibers 704. FIG. 8 is a schematic diagram of a cross-section of a portion of the mesh material 700 taken through line A-A′ of FIG. 7. The warp fibers 702 of the mesh material 700 can be oriented substantially parallel to each other in a first direction, and the shute fibers 704 can be oriented substantially parallel to each other in a second direction. In some implementations, the first and second directions can be substantially perpendicular to each other, such that the warp fibers 702 and the shute fibers 704 are oriented at angles that are substantially equal to 90°. In some implementations, the first and second directions are not substantially particular to each other, such that the warp fibers 702 and the shute fibers 704 are oriented at angles to each other that are less than 90°.

The mesh material 700 can be formed by weaving shute fibers 704 between different warp fibers 702. In some implementations, a shute fiber 704 can be alternately woven over and under successive warp fibers 702 from a first side of the mesh to a second side of the mesh. In some implementations, different weaving patterns can be used to weave shute fibers 704 between different warp fibers 702. For example, shute fibers can be woven over two warp fibers and then under one warp fiber, over two warp fibers, under one warp fiber, etc.

In some implementations, the shute fibers 704 and the warp fibers 702 can include the same or similar materials, but the shute and warp fibers can have different properties, such that the mesh material 700 has different stiffnesses in the first direction and the second direction. For example, in some implementations, the warp fibers 702 can include wires that have a first diameter, and the shute fibers 704 also can include wires but that have a second diameter. In some implementations, the diameters of the warp wires and/or the diameters of the shute wires can be less than 250 microns, can be less than 200 microns, can be less than 150 microns. In some implementations, the second diameter can be at least two times smaller than the first diameter. The smaller diameter shute fibers, as compared with the warp fibers, can allow the shute fibers 704 to bend more easily than the warp fibers 702 and for the mesh material 700 to stretch in a direction along the axes of the shute fibers 704 more easily than in a direction along the axes of the warp fibers 702 and for the mesh material 700 to bend about an axis along a direction parallel to the warp fibers 702 more easily than about an axis along a direction parallel to the shute fibers 704. Thus, when the mesh material 700 is used in a backing film mechanically coupled to an OLED display layer of a light-emitting device and the direction of the warp fibers 702 is aligned with a bending axis of the device, such that relatively little strain is imparted by the mesh material 700 to the display layer when the device is bent about its the bending axis but the mesh material provides relatively rigid support for the device and is relatively resistant to bending about an axis perpendicular to the bending axis.

In some implementations, the shute fibers 704 can have a second diameter that is greater than the first diameter of the warp fibers 702, and/or the warp fibers 702 may be annealed, and therefore not as hard as tempered shute fibers 704, which may permit easier weaving of the shute fibers 704 between the warp fibers 702. For example, the diameters of the warp wires and/or the diameters of the shute wires can be less than 250 microns, can be less than 200 microns, can be less than 150 microns. In such an implementation, when the mesh material 700 is used in a backing film mechanically coupled to an OLED display layer of a light-emitting device and the direction of the shute fibers 704 is aligned with a bending axis of the device, such that relatively little strain is imparted by the mesh material 700 to the display layer when the device is bent about its the bending axis but the mesh material provides relatively rigid support for the device and is relatively resistant to bending about an axis perpendicular to the bending axis.

In some implementations, the material of the shute fibers 704 can be different from the material of the warp fibers 702. For example, in some implementations, the warp fibers 702 can include stainless steel wires, and the shute fibers 704 can include an elastic, low-modulus polymer thread material, such as, for example, spandex, elastane, or elastomer monofilament such as, for example, polyurethane, nitrile, or EDPM. The elastic, low-modulus polymer material of the shute fibers 704 can have a much lower stiffness and a much higher elasticity than the stainless steel wires of the warp fibers 702. Such a combination of different materials for the warp fibers 702 and the shute fibers 704 of the mesh material 700 can allow the shute fibers 704 to bend more easily than the warp fibers 702 and for the mesh material 700 to stretch in a direction along the axes of the shute fibers 704 more easily than in a direction along the axes of the warp fibers 702 and for the mesh material 700 to bend about an axis along a direction parallel to the warp fibers 702 more easily than about an axis along a direction parallel to the shute fibers 704. Thus, when the mesh material 700 is used in a backing film mechanically coupled to an OLED display layer of a light-emitting device and the direction of the warp fibers 702 is aligned with a bending axis of the device, such that relatively little strain is imparted by the mesh material 700 to the display layer when the device is bent about its the bending axis but the mesh material provides relatively rigid support for the device and is relatively resistant to bending about an axis perpendicular to the bending axis.

In some implementations, the shute fibers 704 can include stainless steel and the warp fibers 702 can include an elastic, low-modulus polymer thread material, such as, for example, spandex, elastane, or elastomer monofilament such as, for example, polyurethane, nitrile, or EDPM, and in such an implementation when the mesh material 700 is used in a backing film mechanically coupled to an OLED display layer of a light-emitting device and the direction of the stainless steel shute fibers 704 is aligned with a bending axis of the device, such that relatively little strain is imparted by the mesh material 700 to the display layer when the device is bent about its the bending axis but the mesh material provides relatively rigid support for the device and is relatively resistant to bending about an axis perpendicular to the bending axis.

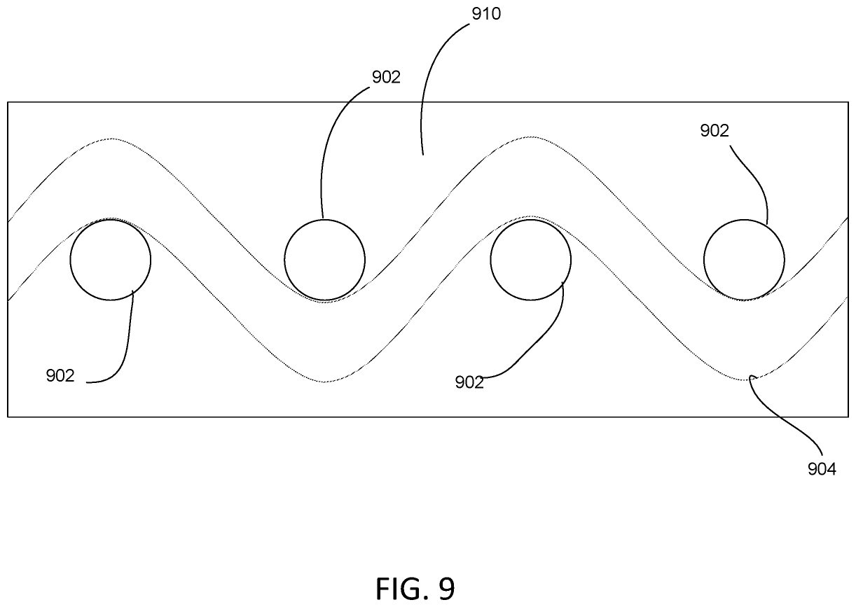

In some implementations, the mesh material 700 having warp fibers 702 and shute fibers 704 that include different materials than the warp fibers or that have different properties than the warp fibers can be used as a precursor material to fabricate a backing film that provides support and strength to a display layer of a light-emitting device. For example, FIGS. 9-11 show cross-sectional views of a mesh material during different stages of a process of fabricating a backing film.

FIG. 9 is a schematic cross-sectional view taken through line A-A′ of FIG. 7 of a woven mesh material having stainless steel warp wires 902 and aluminum shute wires 904 that is encapsulated in a polymer material 910 (e.g., epoxy or polyimide). The woven mesh material can be encapsulated by the polymer material 910 in different ways. For example, the mesh material can be placed in a mold that can be filled with liquid polymer material 910 that can be cured into a hardened state. In another implementation, one or more sheets of pressure-sensitive, partially-cured (e.g., B-staged) polymer (e.g., epoxy or polyimide) material or a thermoplastic “hot melt” material can be pressed into the voids between the warp wires 902 and the shute fibers 904 of the mesh material, with the pressure on the material causing the material to liquefy and to fill the voids. After the polymer material 910 has encapsulated the mesh material and fill the voids between the warp wires 902 and the shute fibers 904, layers of polymer material 910 can be removed from the encapsulating material above and below the plane that includes the warp wires 902 to expose portions of the shute fibers 904 above and below the plane that includes the warp wires 902. For example, the polymer material 910 can be sanded, etched, ablated, plasma etched, etc. to remove material above and below the warp wires 902.

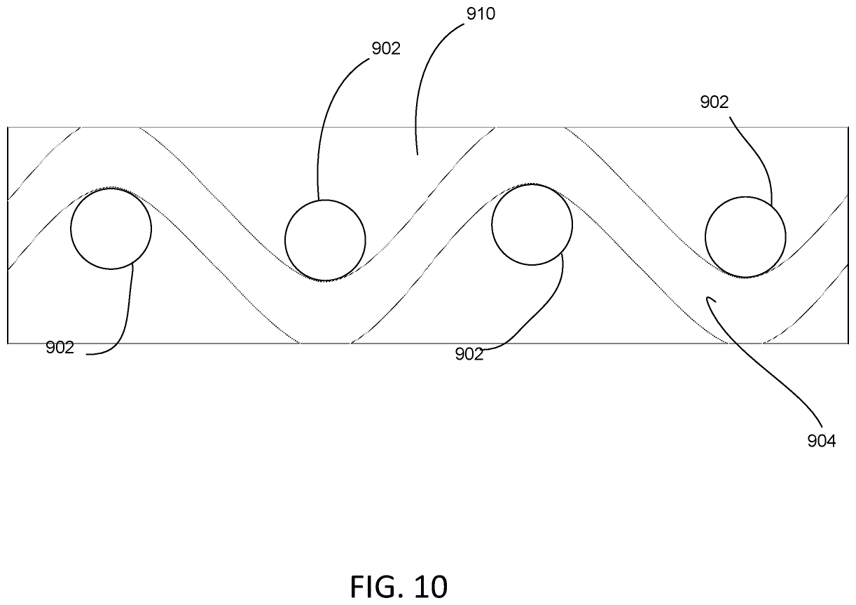

FIG. 10 is a schematic cross-sectional view taken through line A-A′ of FIG. 7 of the woven mesh material with stainless steel warp wires 902 and aluminum shute wires 904 that is encapsulated in the polymer material 910 after portions of the polymer material 910 have been removed to expose the aluminum shute wires 904 to planar surfaces above and below the stainless steel warp wires 902. After the aluminum shute wires 904 are exposed to air outside the encapsulating material 910, an etchant can be used to remove the aluminum material of the shute wires 904 from the woven mesh. For example, the encapsulated woven mesh can be placed into a caustic bath of a basic material (e.g., sodium hydroxide) that attacks the aluminum material, while having little to no effect on the stainless steel material or on the polymer materials, such that the aluminum shute wires 904 are etched away, and removed, from the encapsulated woven mesh. After the aluminum shute wires 904 are removed from the encapsulated woven mesh, the stainless steel warp wires 902 are held in position relative to each other by the cured encapsulating material 910.

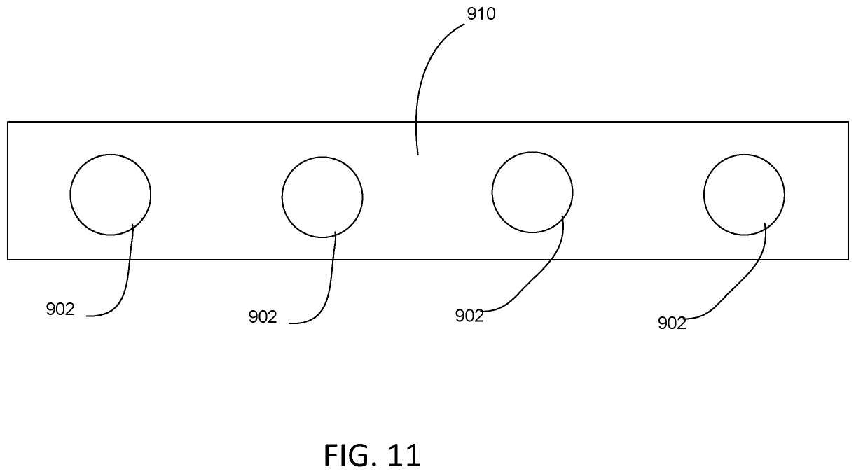

FIG. 11 is a schematic cross-sectional view taken through line B-B′ of FIG. 7 of the woven mesh material with stainless steel warp wires 902 after the aluminum shute wires 904 have been removed by the caustic bath. As seen in FIG. 11 the stainless steel warp wires 902 are encapsulated in the polymer material.

To allow the mesh material with the aluminum shute wires 904 removed to bend and stretch easily when functioning as a backing film for an OLED display layer, the polymer material between the stainless steel warp wires 902 can be broken with a rolling or pressing operation, so that the remaining warp wires form separate sections of the material, which can be attached to a low modulus material film that holds the separate sections together.

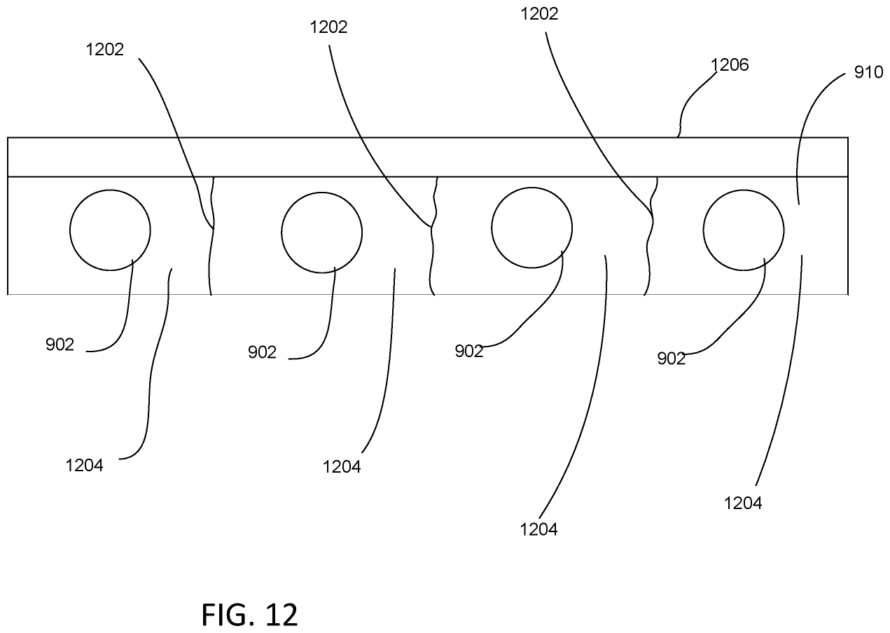

FIG. 12 is a schematic cross-sectional view taken through line B-B′ of FIG. 7 of the woven mesh material with stainless steel warp wires 902 after the aluminum shute wires 904 have been removed by the caustic bath and after the polymer material 910 between the warp wires 902 has been broken along break lines 1202 into separate sections 1204. A low-modulus material film 1206 can be attached to the separate sections of the polymer material prior to breaking the polymer material along the break lines 1202, so that the separate sections are held together by the film 1206 after the polymer material 910 is broken. In some implementations, the low-modulus material film 1206 can include a polyimide material (e.g., Kapton®) film, a nitrile film, an ethylene propylene diene monomer rubber (EDPM) film, or an expanded thermoplastic polyurethane (E-TPU) film. The film 1206 can be mechanically attached to the polymer material by, for example, a thin adhesive layer or by a bonding process.

In some implementations, the polymer material can be broken between the warp wires 902 by pulling the sheet polymer material over a hard, small-radius object, for example, the edge of a desk or bench. In some implementations, the polymer material can be scored or cracked between the warp fibers prior to breaking the polymer material. For example, a jig of mesh material that has the same pitch as that of the mesh material encapsulated with the polymer material to be broken can be used to score the polymer material at all of the break lines 1202 between the encapsulated warp wires 902. In some implementations, the jig of mesh material may include sharp warp fibers (e.g., warp fibers that are coated with a diamond layer) that can be drawn along the polymer material at locations between the warp wires 902 to score the polymer material at predetermined locations. After scoring the polymer material between the warp wires 902, the polymer material can be broken more easily at the predetermined break lines 1202.

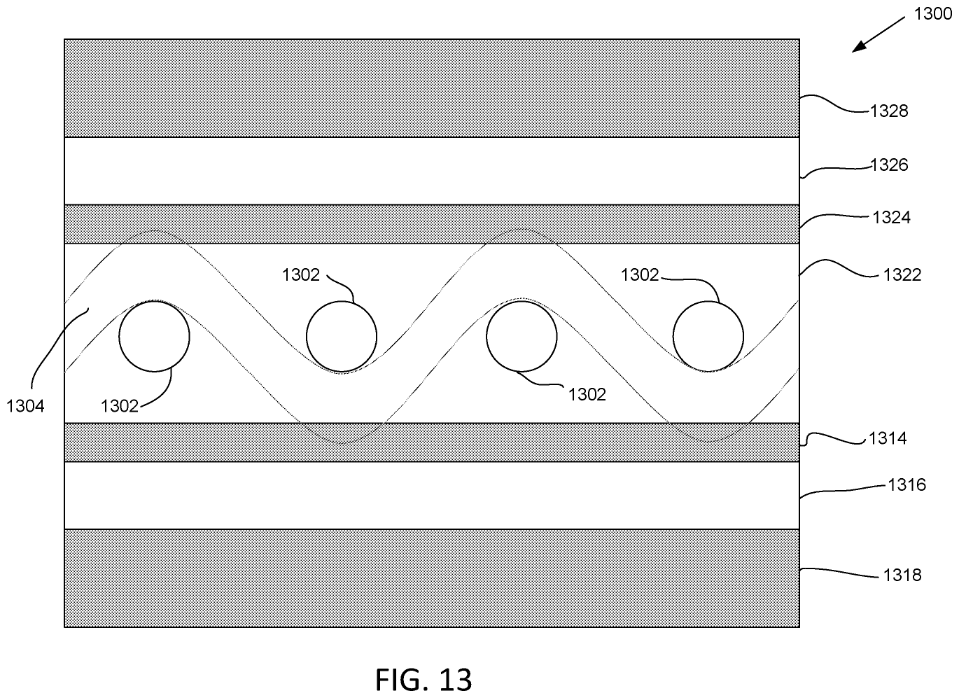

To ensure that the proper amount of polymer material is removed, leaving a predetermined thickness of polymer material that encapsulates the mesh material, before the aluminum shute wires 904 are etched away, a plurality of different color layers of polymer material can be used. FIG. 13 is a schematic cross-sectional view of a structure 1300 that includes a woven mesh material having stainless steel warp wires 1302 and aluminum shute wires 1304 that is encapsulated in a polymer material (e.g., epoxy or polyimide).

The polymer material can include a plurality of layers. For example, the polymer material can include layers 1326, 1316 of light-colored polymer material on a first side and a second side, respectively, of the mesh material that includes the warp fibers 1302 and the shute fibers 1304. On the first side of the structure, the structure 1300 can further include a layer of dark-colored polymer material 1324 on a distal side of a central layer 1322 that includes the mesh material, a light-colored polymer material layer 1326 on a side of layer 1324 distal to the mesh material, and a dark-colored polymer material layer 1328 on a side of layer 1326 distal to the mesh material. On the second side of the structure, the structure 1300 can further include a layer of dark-colored polymer material 1314 on a side of layer 1322 distal to the mesh material, a light-colored polymer material layer 1316 on a side of layer 1314 distal to the mesh material, and a dark-colored polymer material layer 1318 on a side of layer 1316 distal to the mesh material.

In some implementations, each of the polymer material layers 1322, 1314, 1316, 1318, 1322, 1324, 1326, 1328 can include a B-staged sheet of pressure-sensitive epoxy or polyimide. The sheets can liquify and flow when pressure is applied to them, such that layers 1326, 1316 can be pressed into the mesh material to fill voids between the warp fibers 1302 and the shute fibers 1304.

To expose the shute fibers 1304 for etching and to achieve a uniform thickness of polymer material that encapsulates the mesh material when the shute fibers 1304 are exposed for etching, polymer material can be removed from the structure using the following steps. First, surfaces of layers 1318, 1328 can be sanded with a first grit (e.g., 120-180) until a threshold amount (e.g., 50% of the surface area) of layers 1316, 1326 is visible. Then, the remaining surfaces can be sanded with a second grit that is greater than the first grit (e.g., 220-280) until a threshold amount (e.g., 50% of the surface area) of layers 1314, 1324 is visible. Then, the remaining surfaces can be sanded with a third grit that is greater than the second grit (e.g., 320-1000) until a threshold amount (e.g., 50% of the surface area) of layers 1326, 1316 is visible. During the above sanding steps, portions of surfaces can be preferentially sanded to remove remaining portions of exterior layers rather than portions of the next interior layer, as determined by the colors of the different layers, so as to achieve a uniform thickness after the sanding processes are completed.

Once sanding with the third grit is completed, portions of the aluminum shute fibers 1304 are exposed to air and then can be etched. Prior to etching, surfaces of the remaining material can be cleaned (e.g., with isopropyl alcohol). Then, the aluminum of the shute fibers 1304 can be etched away, leaving the stainless steel warp fibers 1302 encapsulated in the polymer material. In addition to removing polymer material by a mechanical process (e.g., sanding), the polymer material also can be removed through other techniques, e.g., through a plasma etching process.

In some implementations (not shown), the shute wires can include stainless steel and the warp wires can include aluminum, in which case the processing described above would leave stainless steel shute fibers encapsulated in the polymer material.

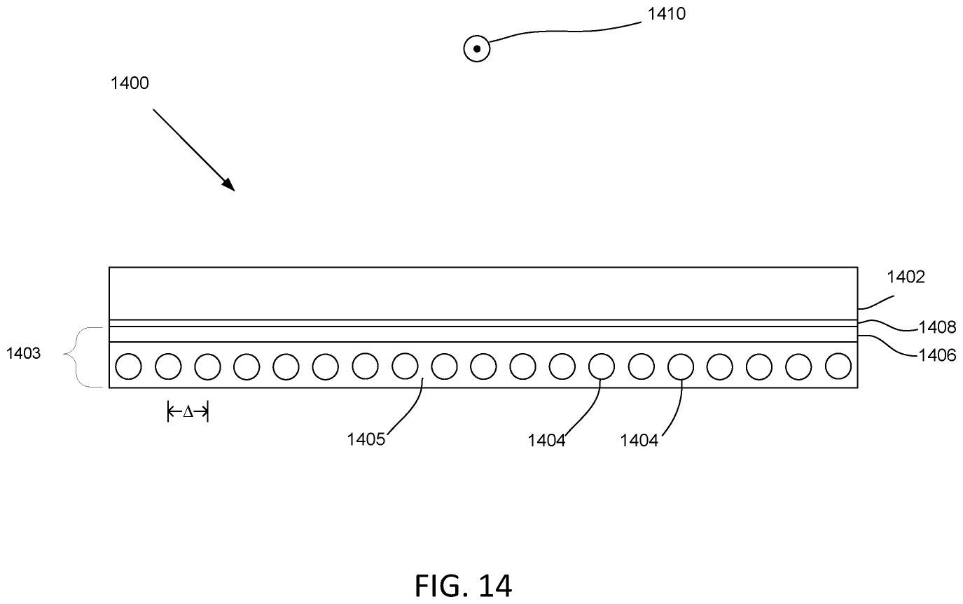

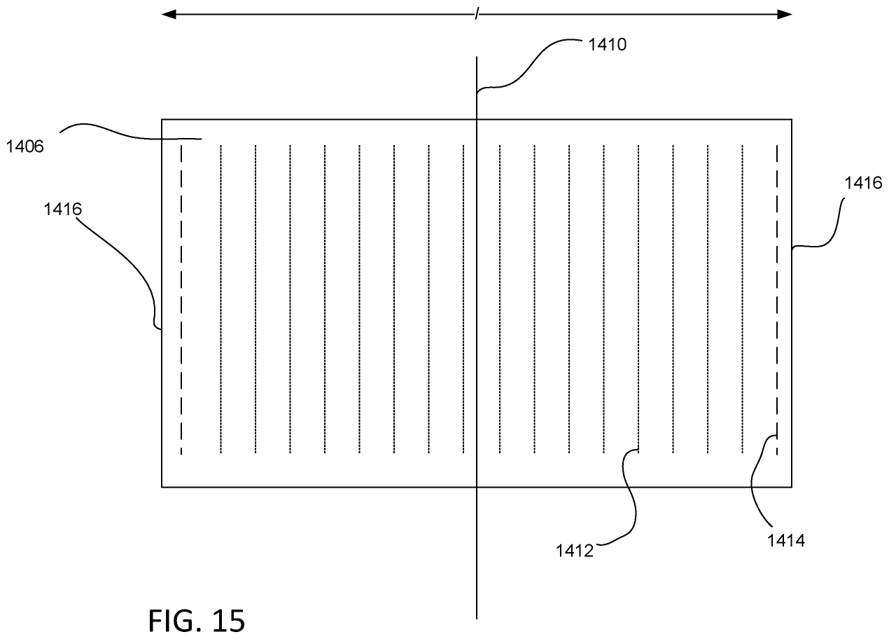

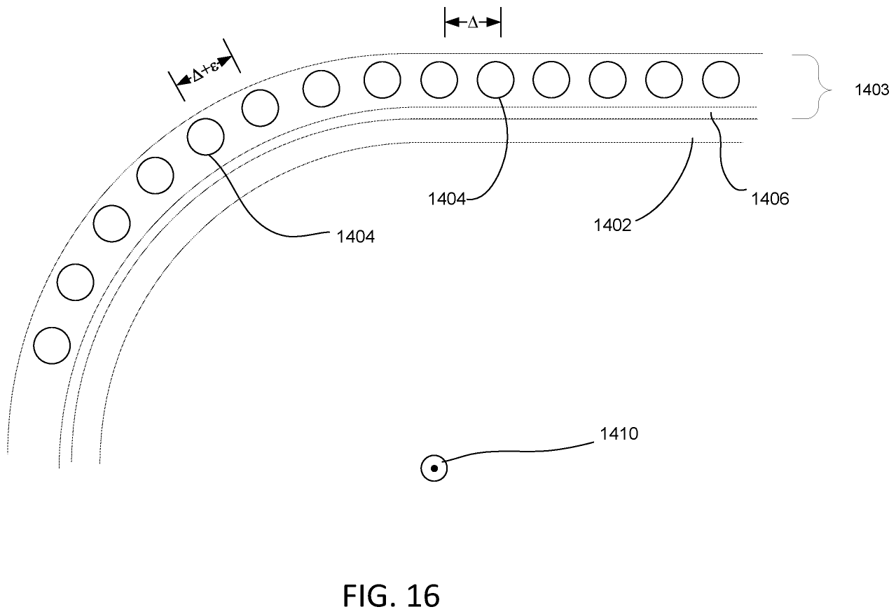

FIG. 14 is a schematic side view of a display device 1400 having a foldable OLED display layer 1402 that is supported by a mesh-based backing film 1403, when the display device is configured in a flat orientation. FIG. 15 is a schematic top view of a low modulus layer 1406 of the display device 1400 having a foldable OLED display layer 1402 that is supported by a mesh-based backing film 1403, when the display device is configured in the flat orientation. FIG. 16 is a schematic side view of the display device 1400 having the OLED display layer 1402 that is supported by the mesh-based backing film 1403, when a portion of the display device is folded and another portion of the display device is flat. The OLED display layer 1402 can be foldable about a bending axis 1410 that runs out of the page in FIGS. 14 and 16 and that is parallel to the surface of the OLED display layer, as shown in FIG. 15.

Referring to FIG. 14, the mesh-based backing film 1403 can include a plurality of parallel metal wires or bars 1404 arranged in a plane. The plane of the wires or bars 1404 can be parallel to a plane of the OLED display layer 1402. The metal wires or bars 1404 can be coupled to a film of low modulus material 1406, and the film of low modulus material 1406 can be coupled to the OLED display layer 1402. The metal wires or bars 1404 can be encapsulated in a polymer material 1405, and the polymer material can include breaks in the material between adjacent the metal wires or bars 1404. The metal wires or bars 1404 can be spaced apart from each other in the plane with a center-to-center distance between adjacent wires or bars of 4.

Referring to FIG. 16, in the flat portion of the device, the metal wires or bars 1404 can be spaced apart from each other in the flat plane with a center-to-center distance between adjacent wires or bars of A. However, in the folded portion of the device, because of a tensile strain applied to the backing film 1403 due to the folding of the device, the metal wires or bars 1404 can be spaced apart from each other in a curved plane with a center-to-center distance between adjacent wires or bars of Δ+ε. With wires or bars 1404 only loosely coupled to each other by the low modulus material film 1406, the backing film 1403 is free to stretch along an arc parallel to the folded portion of the display device 1400 allowing the spacing of between adjacent wires or bars in the backing film proximate to the folded portion to increase.

The mesh based backing film 1403 can include a plurality of parallel metal wires or bars 1404 arranged in a plane. The plane of the wires or bars 1404 can be parallel to a plane of the OLED display layer 1402. The metal wires or bars 1404 can be mechanically coupled to a film of low modulus material 1406, and the film of low modulus material 1406 can be mechanically coupled to the OLED display layer 1402. The metal wires or bars 1404 can be encapsulated in a polymer material.

In an implementation, the film of the low modulus material 1406 can have a modulus of elasticity that is less than 10% of a modulus of the parallel metal wires or bars 1404. In an implementation, the film of the low modulus material 1406 can have a modulus of elasticity that is less than 3% of a modulus of elasticity of the parallel metal wires or bars 1404. In an implementation, the film of the low modulus material 1406 can have a modulus of elasticity that is less than 1% of a modulus of the parallel metal wires or bars 1404. In an implementation, the film of the low modulus material 1406 can have a modulus of elasticity that is less than 0.3% of a modulus of the parallel metal wires or bars 1404. In an implementation, the film of the low modulus material 1406 can have a modulus of elasticity that is less than 0.1% of a modulus of the parallel metal wires or bars 1404. Using a material 1406 that has such a low modulus of elasticity compared to that of the parallel metal wires or bars 1406 can allow backing film 1403 to stretch easily in a direction perpendicular to the bending axis and for the film 1403 to bend easily about the bending axis, without much resistance and without imparting much strain to a display layer of a display device it supports but to support the high-strength parallel metal wires or bars 1404 that provide support for the display device, where the parallel metal wires or bars 1404 are relatively stiff in a direction perpendicular to the bending direction of the device.

The backing film 1403 can be adhesively coupled to the OLED display layer 1402 at one or more coupling points. For example, the backing film 1403 can include an adhesive material 1408 that bonds the film of the low modulus material 1406 to the OLED display layer. In some implementations, the adhesive material 1408 can include a low modulus material that has a modulus of elasticity that is less than 33%, less than 10%, less than 3%, or less than 1% of a modulus of the parallel metal wires or bars 1404. For example, the adhesive material can include silicone. For example, the adhesive material can include acrylate.

In some implementations, the adhesive material 1408 can be provided as a layer of material between the film of low modulus material 1406 and the OLED layer 1402 over a majority of a surface of the low modulus material 1406. In some implementations, the adhesive material 1408 can be provided as one or more beads of material between the film of low modulus material 1406 and the OLED layer 1402. For example, separate and distinct linear beads 1412 of adhesive material 1408 can be provided along a length of one or more of the metal wires or bars 1404 directly above the one or more metal wires or bars, to adhere the film 1406 to the OLED display layer 1402 along the lengths of the metal wires or bars 1404, while leaving the film 1406 unadhered to the display layer 1402 at portions of the film 1406 between the metal wires or bars 1404. In some implementations adhesive material 1408 can be provided along one or more perimeter edges 1414 of the film 1406 to adhere the film 1406 the OLED display layer 1402 along perimeter edges, while leaving the film 1406 within the perimeter edges unadhered to the display layer 1402. The perimeter edges 1414 at which the adhesive material is provided can be within 10% of a length,/, of the film 1406 from and edge 1416 of the film. If the adhesive material 1408 has a modulus of elasticity that is greater than the modulus of elasticity of the film 1406, then when the film 1406 is adhesively coupled to the OLED display layer 1402 over less than the entire surface of the film 1406, the film can stretch more when the OLED display layer 1402 is folded and unfolded than if the film were adhesively attached over its entire surface.

In some implementations, a backing film containing a plurality of metal bars or wires can be created without encapsulating the metal bars or wires. For example, a woven metal mesh can be created, and after weaving the shute fibers through the warp fibers to create the woven mesh, the mesh can be temporarily stabilized by a material that does not encapsulate the fibers of the mesh. While temporarily stabilized, the shute fibers can be eliminated from the mesh, and then the remaining warp fibers can be permanent stabilized by a material to create a backing film that can be used in a flexible OLED display or in another device. Alternatively, while temporarily stabilized, warp fibers can be eliminated from the mesh, and then the remaining shute fibers can be permanent stabilized by a material to create a backing film that can be used in a flexible OLED display or in another device.

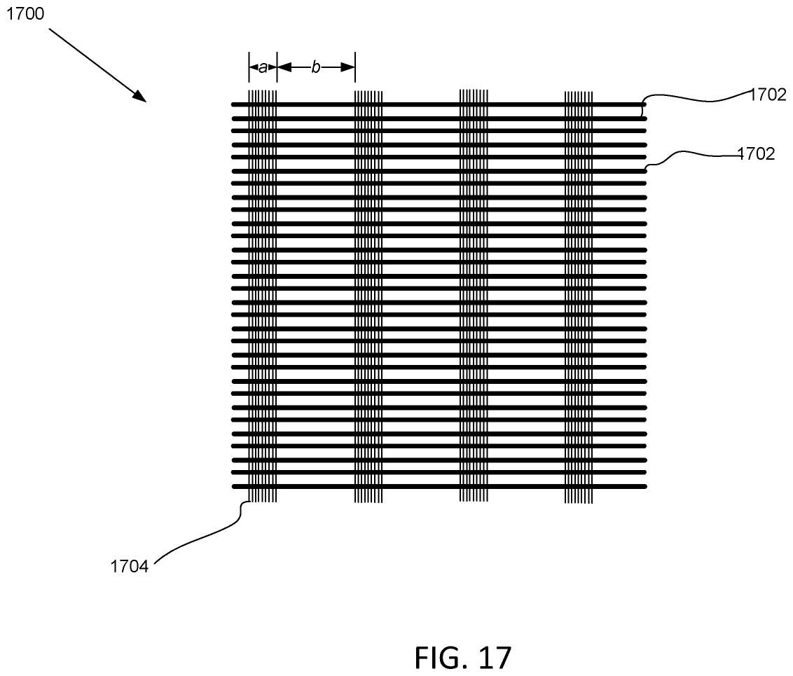

FIG. 17 is a schematic diagram of a mesh material 1700 having warp fibers 1702 and sections of shute fibers 1704, where the sections of shute fibers are displaced from each other, with gaps between adjacent sections of shute fibers 1704. The warp fibers 1702 can have first diameters, and the shute fibers of the sections of shute fibers 1704 can have second diameters. For example, the diameters of the warp fibers and/or the diameters of the shute fibers can be less than 250 microns, can be less than 200 microns, can be less than 150 microns. In some implementations, the warp fibers 1702 can include fibers that are closely-spaced, for example, spaced apart from each other (center-to-center distance) by, on average, less than five times the diameter of the individual warp fibers. In some implementations, each section of shute fibers 1704 can include shute fibers that also are closely-spaced, for example, spaced apart from each other (center-to-center distance) by, on average, less than five times the diameter of the individual shute fibers. In some implementations, the width, b, of gaps between adjacent sections of shute fibers 1704 can be greater than, or at least two times greater than, or at least three times greater than, or at least five times greater than, the width, a, of individual sections of shute fibers 1704. For example, in some implementations, the width, a, of sections of shute fibers 1704 can be greater than 1 cm, and the width, b, of gaps between the adjacent sections can be greater than 2 cm. In some implementations, the width, b, of gaps between the adjacent sections can be less than 10 cm, less than 20 cm, less than 50 cm, or less than 100 cm.

The description of the mesh material 700 can also apply to the mesh material 1700, except that gaps exist between sections of shut fibers 1704 in the mesh material 1700. For example, as with the mesh material 700 shown in FIG. 7, the warp fibers 1702 of the mesh material 1700 can be oriented substantially parallel to each other in a first direction, and the shute fibers 1704 can be oriented substantially parallel to each other in a second direction. The mesh material 1700 can be formed by weaving shute fibers 1704 between different warp fibers 1702. The shute fibers can be woven close to each other in the sections of shute fibers 1704, for example, with the center-to-center distance between adjacent shute fibers being, on average, less than five times the diameters of the individual shute fibers. In some implementations, the shute fibers 1704 can include aluminum and the warp fibers 1702 can include stainless steel. In some implementations, the warp fibers 1702 can include aluminum and the shute fibers 1704 can include stainless steel. Other materials also are possible.

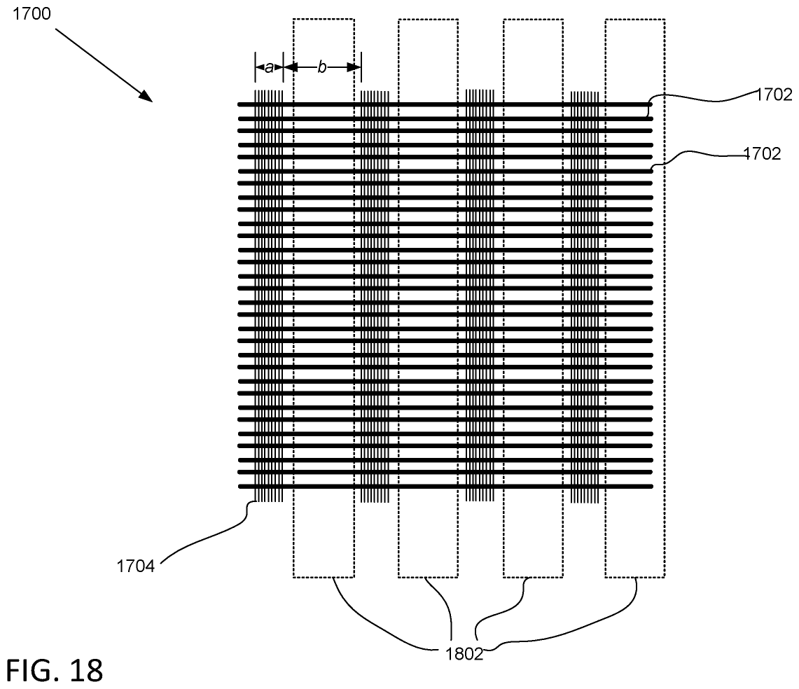

After weaving the mesh material 1700 in which sections of shute fibers 1704 are displaced from each other, the mesh material 1700 can be temporarily stabilized. For example, FIG. 18 is a schematic diagram of a mesh material having warp fibers and sections of shute fibers, where the warp fibers in the gaps of FIG. 17 are temporarily stabilized. As shown in FIG. 18, strips of adhesive tape can be placed (e.g., rolled) across the warp fibers 1702 in the gaps between the sections of shute fibers 1704 on a first side of the mesh material 1700 to stabilize the warp fibers 1702 in the gaps between the sections of the shute fibers 1704. In some implementations, rather than using strips of adhesive tape that adhere only to portions of the warp fibers in the gaps between the sections of shute fibers, a single sheet (or multiple sheets) of adhesive material that covers portions of the warp fibers in the gaps between the sections of shute fibers and portions of the warp fibers that are woven with shute fibers can be applied, and adhered, to the mesh material 1700.

After stabilizing the warp fibers 1702 in the gaps between the sections of shute fibers, the mesh material 1700 can be removed from a loom used to create the mesh material, and then the shute fibers can be removed from the mesh material. For example, if the shute fibers 1704 include aluminum and the warp fibers 1702 include stainless steel, a caustic etchant can be applied to the stabilized mesh material 1700 to remove the aluminum shute fibers 1704.

After the shute fibers 1704 have been removed, leaving substantially parallel warp fibers, which are temporarily stabilized, for example, by the strips of adhesive material 1802, the substantially parallel warp fibers can be permanently stabilized. For example, a low-modulus material film can be attached to a second side of the mesh material, i.e., to the side of the substantially parallel warp fibers 1702 that remain of the mesh material after the shute fibers are removed. In some implementations, the low-modulus material film can include a polyimide material (e.g., Kapton®) film, a nitrile film, an ethylene propylene diene monomer rubber (EDPM) film, or an expanded thermoplastic polyurethane (E-TPU) film. The low-modulus material film can be mechanically attached to the warp fibers 1702 by, for example, a thin adhesive layer or by a bonding process, where the adhesive layer has a greater adhesion to the fibers than the adhesive tape that is used to temporarily stabilize the mesh. After the low-modulus material film is attached to the warp fibers 1702, the strips of adhesive material 1802 that temporarily stabilized the warp fibers 1702 can be removed, for example, by applying a solvent to the adhesive tape to selectively dissolve, and remove, the adhesive tape.

In some implementations, rather than creating the mesh material 1700 described above by leaving gaps between sections of shute fibers, the mesh material 1700 can be created by setting up the warp wires on a loom with gaps between the sections of pluralities of closely-spaced warp wires (e.g., fibers spaced apart by less than five times their diameters) and then weaving closely-spaced shute fibers (e.g., fibers spaced apart by less than five times their diameters) between the warp fibers. When aluminum fibers are used for the warp fibers and stainless steel is used for shute fibers, the stainless steel shute fibers in the gaps between adjacent sections of pluralities of closely-spaced aluminum warp fibers can be temporarily stabilized (e.g., with adhesive tape) until the aluminum fibers are etched away, and then the stainless steel shute wires can be permanently stabilized.

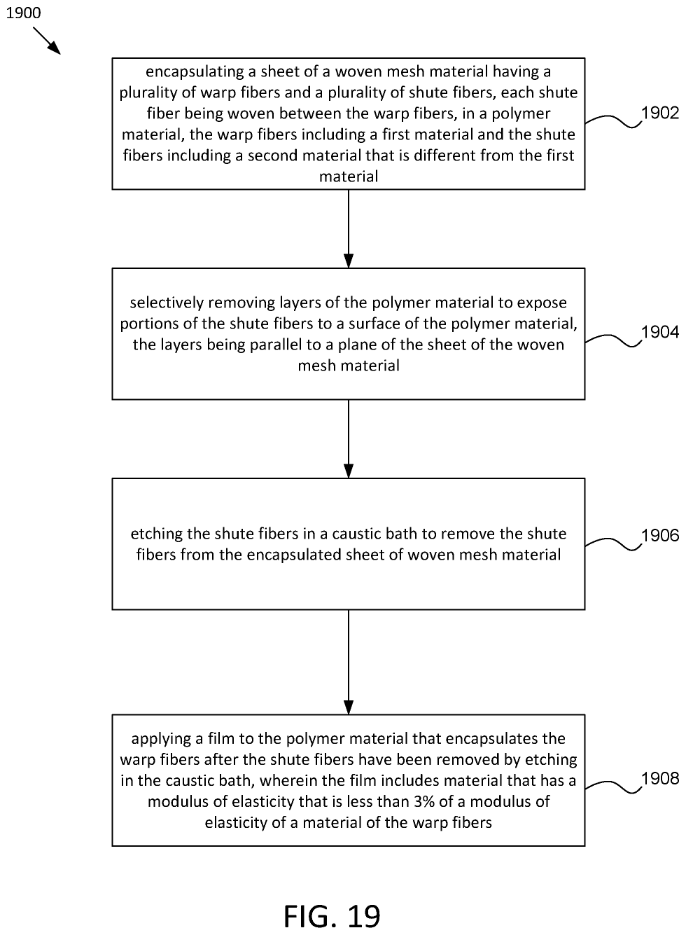

FIG. 19 is a flowchart of a process 1900 of making a backing film. The backing film can be used in a foldable electronic display device having a foldable display layer configured for displaying information to a user, and the backing film has a stiffness in a first direction parallel to a bending axis of a plane of the foldable display layer that is at least ten times higher than a stiffness of the backing film in a second direction perpendicular to the bending axis in the plane of the foldable display layer.

The process 1900 includes encapsulating a sheet of a woven mesh material having a plurality of warp fibers and a plurality of shute fibers, each shute fiber being woven between the warp fibers, in a polymer material, the warp fibers including a first material and the shute fibers including a second material that is different from the first material (1902).

The process 1900 further includes selectively removing layers of the polymer material to expose portions of the shute fibers to a surface of the polymer material, the layers being parallel to a plane of the sheet of the woven mesh material (1904).

The process 1900 further includes etching the shute fibers in a caustic bath to remove the shute fibers from the encapsulated sheet of woven mesh material (1906).

The process 1900 further includes applying a film to the polymer material that encapsulates the warp fibers after the shute fibers have been removed by etching in the caustic bath, wherein the film includes material that has a modulus of elasticity that is less than 3% of a modulus of elasticity of a material of the warp fibers (1908).

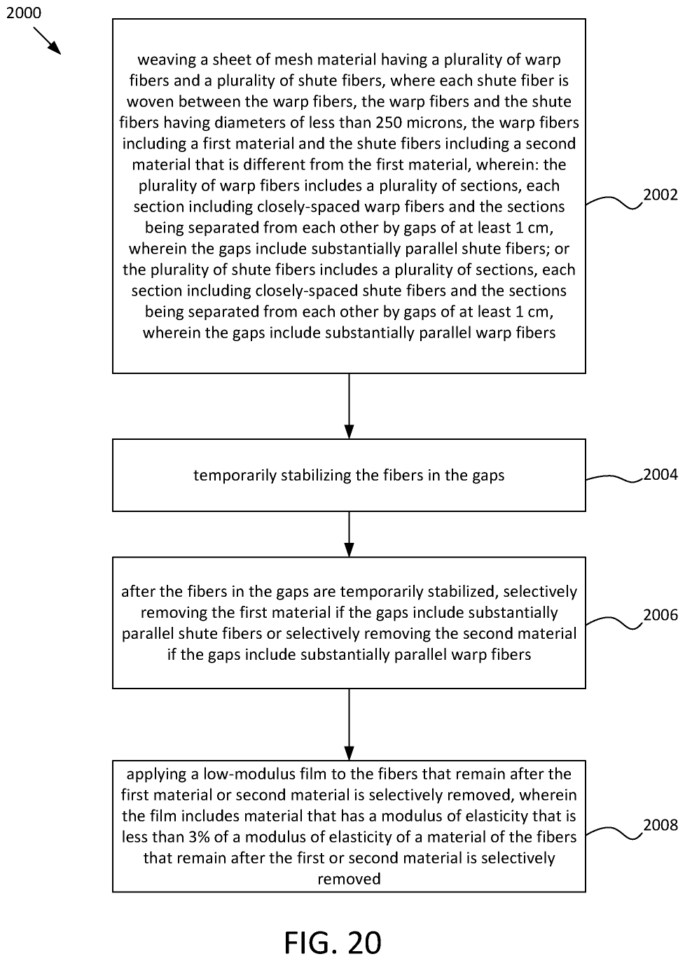

FIG. 20 is another flowchart of a process 2000 of making a backing film. The backing film can be used in a foldable display having a foldable display layer configured for displaying information to a user, with the backing film having a stiffness in a first direction parallel to a bending axis of a plane of the foldable display layer that is at least ten times higher than a stiffness of the backing film in a second direction perpendicular to the bending axis in the plane of the foldable display layer.

The process 2000 includes weaving a sheet of mesh material having a plurality of warp fibers and a plurality of shute fibers (2002), where each shute fiber is woven between the warp fibers, the warp fibers and the shute fibers having diameters of less than 250 microns, the warp fibers including a first material and the shute fibers including a second material that is different from the first material, wherein: the plurality of warp fibers includes a plurality of sections, each section including closely-spaced warp fibers and the sections being separated from each other by gaps of at least 1 cm, wherein the gaps include substantially parallel shute fibers; or the plurality of shute fibers includes a plurality of sections, each section including closely-spaced shute fibers and the sections being separated from each other by gaps of at least 1 cm, wherein the gaps include substantially parallel warp fibers.

The process 2000 further includes temporarily stabilizing the fibers in the gaps (2004).

The process 2000 further includes, after the fibers in the gaps are temporarily stabilized, selectively removing the first material if the gaps include substantially parallel shute fibers or selectively removing the second material if the gaps include substantially parallel warp fibers (2006).

The process 2000 further includes applying a low-modulus film to the fibers that remain after the first material or second material is selectively removed, wherein the film includes material that has a modulus of elasticity that is less than 3% of a modulus of elasticity of a material of the fibers that remain after the first or second material is selectively removed (2008).

In the following, some examples are described.

Example 1: A foldable electronic display device including: a foldable display layer configured for displaying information to a user; and a backing film coupled to the foldable display layer and arranged substantially parallel to a display surface of the foldable display layer. The backing film is configured to have a stiffness in a first direction parallel to a bending axis of a plane of the foldable display layer that is at least ten times higher than a stiffness of the backing film in a second direction perpendicular to the bending axis in the plane of the foldable display layer. The backing film includes a plurality of metal fibers arranged parallel to each other in the first direction and a film that mechanically couples the plurality of metal fibers to each other and that mechanically couples the plurality of metal fibers to the foldable display layer, where the film includes material that has a modulus of elasticity that is less than 3% of a modulus of elasticity of a material of the plurality of metal fibers.

Example 2: The foldable electronic display device of example 1, where the plurality of metal fibers include a stainless steel material.

Example 3: The foldable electronic display device of any of example 1 or example 2, where the film includes a polyimide material.

Example 4: The foldable electronic display device of any of the preceding examples, where the foldable display layer includes an OLED layer.

Example 5: The foldable electronic display device of any of the preceding examples, where a neutral plane of the foldable electronic display device coincides with a plane within the foldable display layer.

Example 6: The foldable electronic display device of any of the preceding examples, where the backing film includes a woven mesh material having warp fibers and shute fibers woven between the warp fibers, where the shute fibers have a modulus of elasticity that is less than 3% of a modulus of elasticity of the warp fibers, and where the plurality of metal fibers include the warp fibers of the woven mesh material.

Example 7: The foldable electronic display device of example 6, where the shute fibers include spandex or elastane.

Example 8: The foldable electronic display device of any of examples 1-5, where the backing film further includes a polymer material that encapsulates the plurality of metal fibers.

Example 9: The foldable electronic display device of example 8, where

the polymer material is broken into a plurality of distinct sections, each section encapsulating a metal fiber of the plurality of metal fibers.

Example 10: The foldable electronic display device of any of examples 8 or 9, where the polymer material includes voids corresponding to locations of shute fibers of a woven mesh material, which have been removed from the mesh material, and where the plurality of metal fibers include warp fibers of the woven mesh material.

Example 11: The foldable electronic display device of example 10, where the warp fibers include stainless steel and where the shute fibers include aluminum.

Example 12: The foldable electronic display device of any of the preceding examples, where the plurality of metal fibers have diameters that are less than 250 microns and that are spaced apart from each other by, on average, less than five times a diameter of individual fibers of the plurality of metal fibers.

Example 13: A method of making a backing film for a foldable electronic display device having a foldable display layer configured for displaying information to a user, the backing film having a stiffness in a first direction parallel to a bending axis of a plane of the foldable display layer that is at least ten times higher than a stiffness of the backing film in a second direction perpendicular to the bending axis in the plane of the foldable display layer, the method including: encapsulating a sheet of a woven mesh material having a plurality of warp fibers and a plurality of shute fibers, each shute fiber being woven between the warp fibers, in a polymer material, the warp fibers including a first material and the shute fibers including a second material that is different from the first material; selectively removing layers of the polymer material to expose portions of the shute fibers to a surface of the polymer material, the layers being parallel to a plane of the sheet of the woven mesh material; etching the shute fibers in a caustic bath to remove the shute fibers from the encapsulated sheet of woven mesh material; applying a film to the polymer material that encapsulates the warp fibers after the shute fibers have been removed by etching in the caustic bath, where the film includes material that has a modulus of elasticity that is less than 3% of a modulus of elasticity of a material of the warp fibers.

Example 14: The method of example 13, where the warp fibers include stainless steel, and where the shute fibers include aluminum.

Example 15: The method of any of examples 13-14, where the film includes a polyimide material.

Example 16: The method of any of examples 13-15, where the foldable display layer includes an OLED layer.

Example 17: The method of any of examples 13-16, where a neutral plane of the foldable electronic display device coincides with a plane within the display layer.

Example 18: The method of any of examples 13-17, further comprising breaking the polymer material into a plurality of distinct sections, each section encapsulating a warp fiber of the plurality of warp fibers.

Example 19: A method of making a backing film for a foldable display having a foldable display layer configured for displaying information to a user, the backing film having a stiffness in a first direction parallel to a bending axis of a plane of the foldable display layer that is at least ten times higher than a stiffness of the backing film in a second direction perpendicular to the bending axis in the plane of the foldable display layer, the method including: weaving a sheet of mesh material having a plurality of warp fibers and a plurality of shute fibers, each shute fiber being woven between the warp fibers, the warp fibers and the shute fibers having diameters of less than 250 microns, the warp fibers including a first material and the shute fibers including a second material that is different from the first material, where: the plurality of warp fibers includes a plurality of sections, each section including closely-spaced warp fibers and the sections being separated from each other by gaps of at least 1 cm, where the gaps include substantially parallel shute fibers; or the plurality of shute fibers includes a plurality of sections, each section including closely-spaced shute fibers and the sections being separated from each other by gaps of at least 1 cm, where the gaps include substantially parallel warp fibers; temporarily stabilizing the fibers in the gaps; after the fibers in the gaps are temporarily stabilized, selectively removing the first material if the gaps include substantially parallel shute fibers or selectively removing the second material if the gaps include substantially parallel warp fibers; and applying a low-modulus film to the fibers that remain after the first material or second material is selectively removed, where the film includes material that has a modulus of elasticity that is less than 3% of a modulus of elasticity of a material of the fibers that remain after the first or second material is selectively removed.

Example 20: The method of example 19, where selectively removing the first or second material includes etching the woven mesh in a caustic bath.

Example 21: An apparatus for making a backing film for a foldable electronic display device having a foldable display layer configured for displaying information to a user, the backing film having a stiffness in a first direction parallel to a bending axis of a plane of the foldable display layer that is at least ten times higher than a stiffness of the backing film in a second direction perpendicular to the bending axis in the plane of the foldable display layer, the apparatus including: means for encapsulating a sheet of a woven mesh material having a plurality of warp fibers and a plurality of shute fibers, each shute fiber being woven between the warp fibers, in a polymer material, the warp fibers including a first material and the shute fibers including a second material that is different from the first material; means for selectively removing layers of the polymer material to expose portions of the shute fibers to a surface of the polymer material, the layers being parallel to a plane of the sheet of the woven mesh material; means for etching the shute fibers in a caustic bath to remove the shute fibers from the encapsulated sheet of woven mesh material; and means for applying a film to the polymer material that encapsulates the warp fibers after the shute fibers have been removed by etching in the caustic bath, where the film includes material that has a modulus of elasticity that is less than 3% of a modulus of elasticity of a material of the warp fibers.

Example 21: The apparatus of example 20, where the warp fibers include stainless steel, and where the shute fibers include aluminum.

Example 22: The apparatus of any of examples 20-21, where the film includes a polyimide material.

Example 23: The apparatus of any of examples 20-22, where the foldable display layer includes an OLED layer.

Example 24: The apparatus of any of examples 20-23, where a neutral plane of the foldable electronic display device coincides with a plane within the display layer.

Example 25: The apparatus of any of examples 20-24, further comprising breaking the polymer material into a plurality of distinct sections, each section encapsulating a warp fiber of the plurality of warp fibers.

Example 26: An apparatus for making a backing film for a foldable display having a foldable display layer configured for displaying information to a user, the backing film having a stiffness in a first direction parallel to a bending axis of a plane of the foldable display layer that is at least ten times higher than a stiffness of the backing film in a second direction perpendicular to the bending axis in the plane of the foldable display layer, the apparatus including: means for weaving a sheet of mesh material having a plurality of warp fibers and a plurality of shute fibers, each shute fiber being woven between the warp fibers, the warp fibers and the shute fibers having diameters of less than 250 microns, the warp fibers including a first material and the shute fibers including a second material that is different from the first material, where: the plurality of warp fibers includes a plurality of sections, each section including closely-spaced warp fibers and the sections being separated from each other by gaps of at least 1 cm, where the gaps include substantially parallel shute fibers; or the plurality of shute fibers includes a plurality of sections, each section including closely-spaced shute fibers and the sections being separated from each other by gaps of at least 1 cm, where the gaps include substantially parallel warp fibers; means for temporarily stabilizing the fibers in the gaps; means for, after the fibers in the gaps are temporarily stabilized, selectively removing the first material if the gaps include substantially parallel shute fibers or selectively removing the second material if the gaps include substantially parallel warp fibers; and applying a low-modulus film to the fibers that remain after the first material or second material is selectively removed, where the film includes material that has a modulus of elasticity that is less than 3% of a modulus of elasticity of a material of the fibers that remain after the first or second material is selectively removed.

Example 27: The apparatus of example 26, where selectively removing the first or second material includes etching the woven mesh in a caustic bath.

The devices and apparatuses described herein can be included as part of a computing device, that includes, for example, a processor for executing instructions and a memory for storing the executable instructions. Specific structural and functional details disclosed herein are merely representative for purposes of describing example embodiments. Example embodiments, however, be embodied in many alternate forms and should not be construed as limited to only the embodiments set forth herein.

The devices and apparatuses described herein can be included as part of a computing device, that includes, for example, a processor for executing instructions and a memory for storing the executable instructions. Specific structural and functional details disclosed herein are merely representative for purposes of describing example embodiments. Example embodiments, however, be embodied in many alternate forms and should not be construed as limited to only the embodiments set forth herein.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term and/or includes any and all combinations of one or more of the associated listed items.

It will be understood that when an element is referred to as being connected or coupled to another element, it can be directly connected or coupled to the other element or intervening elements may be present. In contrast, when an element is referred to as being directly connected or directly coupled to another element, there are no intervening elements present. Other words used to describe the relationship between elements should be interpreted in a like fashion (e.g., between versus directly between, adjacent versus directly adjacent, etc.).

The terminology used herein is for the purpose of describing particular embodiments only and is not intended to be limiting of example embodiments. As used herein, the singular forms a, an and the are intended to include the plural forms as well, unless the context clearly indicates otherwise. It will be further understood that the terms comprises, comprising, includes and/or including, when used herein, specify the presence of stated features, integers, steps, operations, elements and/or components, but do not preclude the presence or addition of one or more other features, integers, steps, operations, elements, components and/or groups thereof.

It should also be noted that in some alternative implementations, the functions/acts noted may occur out of the order noted in the figures. For example, two figures shown in succession may in fact be executed concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

It should be borne in mind, however, that all of these and similar terms are to be associated with the appropriate physical quantities and are merely convenient labels applied to these quantities. Unless specifically stated otherwise, or as is apparent from the discussion, terms such as processing or computing or calculating or determining of displaying or the like, refer to the action and processes of a computer system, or similar electronic computing device, that manipulates and transforms data represented as physical, electronic quantities within the computer system's registers and memories into other data similarly represented as physical quantities within the computer system memories or registers or other such information storage, transmission or display devices.

Lastly, it should also be noted that whilst the accompanying claims set out particular combinations of features described herein, the scope of the present disclosure is not limited to the particular combinations hereafter claimed, but instead extends to encompass any combination of features or embodiments herein disclosed irrespective of whether or not that particular combination has been specifically enumerated in the accompanying claims at this time.

1. A foldable electronic display device comprising:
a foldable display layer configured for displaying information to a user; and
a backing film coupled to the foldable display layer and arranged substantially parallel to a display surface of the foldable display layer, the backing film configured to have a stiffness in a first direction parallel to a bending axis of a plane of the foldable display layer that is at least ten times higher than a stiffness of the backing film in a second direction perpendicular to the bending axis in the plane of the foldable display layer,
wherein the backing film includes:
a plurality of metal fibers arranged parallel to each other in the first direction; and
a film that mechanically couples the plurality of metal fibers to each other and that mechanically couples the plurality of metal fibers to the foldable display layer, wherein the film includes material that has a modulus of elasticity that is less than 3% of a modulus of elasticity of a material of the plurality of metal fibers.

2. The foldable electronic display device of claim 1, wherein the plurality of metal fibers include a stainless steel material.

3. The foldable electronic display device of claim 1, wherein the film includes a polyimide material.

4. The foldable electronic display device of claim 1, wherein the foldable display layer includes an OLED layer.

5. The foldable electronic display device of claim 1, wherein a neutral plane of the foldable electronic display device coincides with a plane within the foldable display layer.

6. The foldable electronic display device of claim 1, wherein the backing film includes a woven mesh material having warp fibers and shute fibers woven between the warp fibers, wherein the shute fibers have a modulus of elasticity that is less than 3% of a modulus of elasticity of the warp fibers, and wherein the plurality of metal fibers include the warp fibers of the woven mesh material.

7. The foldable electronic display device of claim 6, wherein the shute fibers include spandex or elastane.

8. The foldable electronic display device of claim 1, wherein the backing film further includes a polymer material that encapsulates the plurality of metal fibers.

9. The foldable electronic display device of claim 8, wherein the polymer material is broken into a plurality of distinct sections, each section encapsulating a metal fiber of the plurality of metal fibers.

10. The foldable electronic display device of claim 8, wherein the polymer material includes voids corresponding to locations of shute fibers of a woven mesh material, which have been removed from the mesh material, and wherein the plurality of metal fibers include warp fibers of the woven mesh material.

11. The foldable electronic display device of claim 10, wherein the warp fibers include stainless steel and wherein the shute fibers include aluminum.

12. The foldable electronic display device of claim 1, wherein the plurality of metal fibers have diameters that are less than 250 microns and that are spaced apart from each other by, on average, less than five times a diameter of individual fibers of the plurality of metal fibers.

13. A method of making a backing film for a foldable electronic display device having a foldable display layer configured for displaying information to a user, the backing film having a stiffness in a first direction parallel to a bending axis of a plane of the foldable display layer that is at least ten times higher than a stiffness of the backing film in a second direction perpendicular to the bending axis in the plane of the foldable display layer, the method comprising:
encapsulating a sheet of a woven mesh material having a plurality of warp fibers and a plurality of shute fibers, each shute fiber being woven between the warp fibers, in a polymer material, the warp fibers including a first material and the shute fibers including a second material that is different from the first material;
selectively removing layers of the polymer material to expose portions of the shute fibers to a surface of the polymer material, the layers being parallel to a plane of the sheet of the woven mesh material;
etching the shute fibers in a caustic bath to remove the shute fibers from the encapsulated sheet of woven mesh material; and
applying a film to the polymer material that encapsulates the warp fibers after the shute fibers have been removed by etching in the caustic bath, wherein the film includes material that has a modulus of elasticity that is less than 3% of a modulus of elasticity of a material of the warp fibers.

14. The method of claim 13, wherein the warp fibers include stainless steel, and wherein the shute fibers include aluminum.

15. The method of claim 13, wherein the film includes a polyimide material.

16. The method of claim 13, wherein the foldable display layer includes an OLED layer.

17. The method of claim 13, wherein a neutral plane of the foldable electronic display device coincides with a plane within the display layer.

18. The method of claim 13, further comprising breaking the polymer material into a plurality of distinct sections, each section encapsulating a warp fiber of the plurality of warp fibers.

19. A method of making a backing film for a foldable display having a foldable display layer configured for displaying information to a user, the backing film having a stiffness in a first direction parallel to a bending axis of a plane of the foldable display layer that is at least ten times higher than a stiffness of the backing film in a second direction perpendicular to the bending axis in the plane of the foldable display layer, the method comprising:
weaving a sheet of mesh material having a plurality of warp fibers and a plurality of shute fibers, each shute fiber being woven between the warp fibers, the warp fibers and the shute fibers having diameters of less than 250 microns, the warp fibers including a first material and the shute fibers including a second material that is different from the first material, wherein: the plurality of warp fibers includes a plurality of sections, each section including closely-spaced warp fibers and the sections being separated from each other by gaps of at least 1 cm, wherein the gaps include substantially parallel shute fibers; or the plurality of shute fibers includes a plurality of sections, each section including closely-spaced shute fibers and the sections being separated from each other by gaps of at least 1 cm, wherein the gaps include substantially parallel warp fibers;
temporarily stabilizing the fibers in the gaps;
after the fibers in the gaps are temporarily stabilized, selectively removing the first material if the gaps include substantially parallel shute fibers or selectively removing the second material if the gaps include substantially parallel warp fibers; and
applying a low-modulus film to the fibers that remain after the first material or second material is selectively removed, wherein the film includes material that has a modulus of elasticity that is less than 3% of a modulus of elasticity of a material of the fibers that remain after the first or second material is selectively removed.

20. The method of claim 19, wherein selectively removing the first or second material includes etching the woven mesh in a caustic bath.
